(19) United States
(12) Patent Application Publication
(10) Pub. No.: US 2024/0280888 A1
(43) Pub. Date: Aug. 22, 2024

(54) EXTREME ULTRA-VIOLET MASK AND MANUFACTURING METHOD THEREOF

(71) Applicant: SAMSUNG ELECTRONICS CO., LTD., SUWON-SI (KR)

(72) Inventors: Sunpyo Lee, Suwon-si (KR); Minchang Kim, Suwon-si (KR); Yoontaek Han, Suwon-si (KR)

(21) Appl. No.: 18/407,763

(22) Filed: Jan. 9, 2024

(30) Foreign Application Priority Data
Feb. 17, 2023 (KR) 10-2023-0021592

(51) Int. Cl. G03F 1/24

(52) U.S. Cl. CPC G03F 1/24

(57) ABSTRACT

The present disclosure describes an extreme ultra-violet (EUV) mask having improved reliability and durability and a manufacturing method thereof. The extreme ultra-violet mask includes a substrate, a reflective multilayer disposed on the substrate and comprising a plurality of each of two types of material layers alternately stacked on each other, and an absorption layer disposed on the reflective multilayer, wherein the absorption layer comprises a central transfer region and a non-transfer region, wherein an opening through the non-transfer region of the absorption layer forms a defect avoidance pattern that exposes a beam calibration point of the reflective multilayer.

### CROSS-REFERENCE TO RELATED APPLICATION

This application is based on and claims priority under 35 USC § 119 to Korean Patent Application No. 10-2023-0021592 filed on Feb. 17, 2023 in the Korean Intellectual Property Office, the contents of which are incorporated by reference herein in their entirety.

### BACKGROUND

The present disclosure relates to a mask and a manufacturing method thereof, and more particularly, to an extreme ultra-violet (EUV) mask used in an EUV exposure process and a manufacturing method thereof.

### DESCRIPTION OF THE RELATED ART

Technological advances in the design of semiconductor materials have resulted in new generations of integrated circuits (ICs) with each generation having smaller and more complex circuits than the previous generation. With each new generation, the functional density (i.e., the number of interconnected devices per chip area) has generally increased while geometry size (i.e., the smallest component or line that can be created using a fabrication process) has gradually decreased. The reduced sizes of patterns formed on the semiconductor are decreasing to meet consumer demand for excellent performance and low price.

Moreover, ICs include patterns that influence the degree of integration of semiconductor memory devices. In some cases, such patterns are generated using photolithography masks. As a result of the reduced pattern and IC size, extreme ultraviolet (EUV) light is used in a lithographic process for transferring patterns from a mask to a semiconductor wafer. In some cases, the wavelength of a light source used in a lithography process has been shortened to meet the size and other technical requirements. For example, in a lithography process, g-line (436 nm) and i-line (365 nm) have been used. In some cases, light in a deep ultra-violet (DUV) band and light in an EUV band are used. However, the light in the EUV band is absorbed by refractive optical materials and EUV lithography may generally be performed using a reflective rather than a refractive optical system which results in a blister defect. Therefore, there is a need in the art for systems and methods that can avoid the occurrence of blister defects while optimizing the semiconductor manufacturing process.

### SUMMARY

The present disclosure describes a semiconductor memory device having reduced blister defects. In some cases, an extreme ultraviolet (EUV) mask is used in the manufacture of patterns in an IC. For example, the EUV mask is used to prevent or minimize blister defects by opening a beam calibration point (BCP) through a defect avoidance pattern (DAP). Accordingly, embodiments of the present disclosure include an extreme ultra-violet (EUV) mask having improved reliability and durability and a manufacturing method thereof.

Additionally, the problem to be solved by the present disclosure is not limited to the above-mentioned problems, and other problems may be clearly understood by those skilled in the art from the description below.

According to an aspect of the present disclosure, there is provided an extreme ultra-violet mask including a substrate, a reflective multilayer disposed on the substrate, wherein the reflective multilayer comprises a plurality of each of two types of material layers and including tens of two types of material layers that are alternately stacked on each other, and an absorption layer disposed on the reflective multilayer, wherein the absorption layer comprises a central transfer region and a non-transfer region, wherein an opening through the non-transfer region of the absorption layer forms a defect avoidance pattern that exposes a beam calibration point of the reflective multilayer.

According to another aspect of the present disclosure, there is provided a method of manufacturing an extreme ultra-violet mask including forming a reflective multilayer by alternately stacking two materials on a substrate, inspecting the reflective multilayer by scanning the reflective multilayer with a laser beam, forming an absorption layer on the reflective multilayer, wherein the absorption layer comprises a central transfer region and a non-transfer region, and forming one or more holes in the absorption layer within the non-transfer region, wherein the one or more holes comprise a defect avoidance pattern exposing a beam calibration point of the reflective multilayer.

According to another aspect of the present disclosure, there is provided a method of manufacturing an extreme ultra-violet mask including forming a reflective multilayer by alternately stacking two materials on a substrate, inspecting the reflective multilayer by scanning the reflective multilayer with a laser beam, forming an absorption layer on the reflective multilayer, wherein the absorption layer comprises a central transfer region and a non-transfer region, and forming a plurality of process patterns in the non-transfer region, wherein a first process pattern, which is one of the plurality of process patterns, exposes a beam calibration point of the reflective multilayer.

According to another aspect of the present disclosure, there is provided a method of manufacturing an extreme ultra-violet mask, the method including forming a reflective multilayer by alternately stacking two materials on a substrate, inspecting the reflective multilayer by scanning the reflective multilayer with a laser beam to, forming an absorption layer on the reflective multilayer, wherein the absorption layer comprises a central transfer region and a non-transfer region, and wherein the inspecting includes performing beam calibration at a beam calibration point and performing scanning with a multi-laser beam, wherein a blister defect is prevented based on the beam calibration.

### BRIEF DESCRIPTION OF THE DRAWINGS

Embodiments will be more clearly understood from the following detailed description taken in conjunction with the accompanying drawings:

FIG. 1 is a plan view of an extreme ultra-violet (EUV) mask according to an embodiment;

FIG. 2A is a plan view illustrating enlarged portion A of the EUV mask of FIG. 1;

FIG. 2B is a cross-sectional view taken along line I-I′ of FIG. 2A;

FIG. 3A is a plan view illustrating the enlarged portion A of the EUV mask of FIG. 1;

FIG. 3B is a cross-sectional view taken along line II-II′ of FIG. 3A;

FIGS. 4A to 4D are plan views and photographs illustrating defects of an EUV mask of a comparative example;

FIG. 5 is a plan view of an EUV mask according to an embodiment;

FIGS. 6A to 6D are plan views illustrating enlarged portions 1 to 4 of FIG. 5;

FIG. 7 is a flowchart schematically illustrating a manufacturing method of an EUV mask of FIG. 1, according to an embodiment;

FIGS. 8A to 8D are cross-sectional views and plan views of an EUV mask corresponding to operations of a method of manufacturing an EUV mask of FIG. 7;

FIG. 9 is a flowchart illustrating a manufacturing method of an EUV mask of FIG. 5, according to an embodiment;

FIGS. 10A and 10B are cross-sectional and plan views of an EUV mask corresponding to the manufacturing method of an EUV mask of FIG. 9; and

FIG. 11 is a flowchart schematically illustrating a manufacturing method of an EUV mask, according to an embodiment.

### DETAILED DESCRIPTION OF THE EMBODIMENTS

The present disclosure describes a semiconductor memory device having reduced blister defects. In some cases, an extreme ultraviolet (EUV) mask is used in the manufacture of patterns in an IC. For example, the EUV mask is used to prevent or minimize blister defects by opening a beam calibration point (BCP) through a defect avoidance pattern (DAP).

Conventional semiconductor devices include an EUV mask that has a layer exposed to the openings which enhances strength of the layer and reduces oxidation. Additionally, in some cases, an EUV mask includes a structure in which some layers are added below a light absorption pattern to prevent a blister defect. However, such layers are porous and hence cannot be a pattern structure. Thus, conventional devices do not disclose a mask structure that is capable of preventing a blister defect by forming a dummy pattern in a lower region of a beam calibration point of an EUV mask.

Embodiments of the present disclosure include a UV mask that may prevent or minimize the occurrence of blister defects in an exposure process using an EUV mask by opening a beam calibration point (BCP) through a defect avoidance pattern (DAP). In addition, by exposing the BCP using a process pattern essential/common to the EUV mask, resource waste, such as additional processes/facilities and TAT loss during a manufacturing process of the EUV mask, while avoiding the occurrence of blister defects, thereby contributing to optimization of the manufacturing process.

According to embodiments of the present disclosure, an extreme ultra-violet mask is provided. In some cases, the mask comprises a substrate, a reflective multilayer, and an absorption layer. The reflective multilayer is disposed on the substrate and comprises a plurality of each of two types of material layers alternately stacked on each other. The absorption layer is disposed on the reflective multilayer and comprises a central transfer region and a non-transfer region. In some cases, an opening through the non-transfer region of the absorption layer forms a defect avoidance pattern that exposes a beam calibration point of the reflective multilayer.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. The features described herein may be embodied in different forms and are not to be construed as being limited to the example embodiments described herein. Rather, the example embodiments described herein have been provided merely to illustrate some of the many possible ways of implementing the methods, apparatuses, and/or systems described herein that will be apparent after an understanding of the disclosure of this application.

The present disclosure may be modified in multiple alternate forms, and thus specific embodiments will be exemplified in the drawings and described in detail. In the present specification, when a component (or a region, a layer, a portion, etc.) is referred to as being “on,” “connected to,” or “coupled to” another component, it means that the component may be directly disposed on/connected to/coupled to the other component, or that a third component may be disposed therebetween.

Like reference numerals may refer to like components throughout the specification and the drawings. It is noted that while the drawings are intended to illustrate actual relative dimensions of a particular embodiment of the specification, the present disclosure is not necessarily limited to the embodiments shown. The term “and/or” includes all combinations of one or more of which associated configurations may define.

It will be understood that, although the terms “first,” “second,” etc. may be used herein to describe various components, these components should not necessarily be limited by these terms. These terms are only used to distinguish one component from another. For example, a first component could be termed a second component, and, similarly, a second component could be termed a first component, without departing from the scope of the inventive concept. The terms of a singular form may include plural forms unless the context clearly indicates otherwise.

Additionally, terms such as “below,” “under,” “on,” and “above” may be used to describe the relationship between components illustrated in the figures. The terms are used as a relative concept and are described with reference to the direction indicated in the drawings. It should be understood that the terms “comprise,” “include,” or “have” are intended to specify the presence of stated features, integers, steps, operations, components, parts, or combinations thereof in the disclosure, but do not preclude the presence or addition of one or more other features, integers, steps, operations, components, parts, or combinations thereof.

In the present specification, although terms such as first and second are used to describe various elements or components, it goes without saying that these elements or components are not limited by these terms. These terms are only used to distinguish a single element or component from other elements or components. Therefore, it goes without saying that a first element or component referred to below may be a second element or component within the technical idea of the present invention.

Hereinafter, embodiments including a method for reducing a blister defect of a semiconductor memory device are described in detail with reference to the accompanying drawings. The same reference numerals are used for the same components in the drawings, and redundant descriptions thereof are omitted.

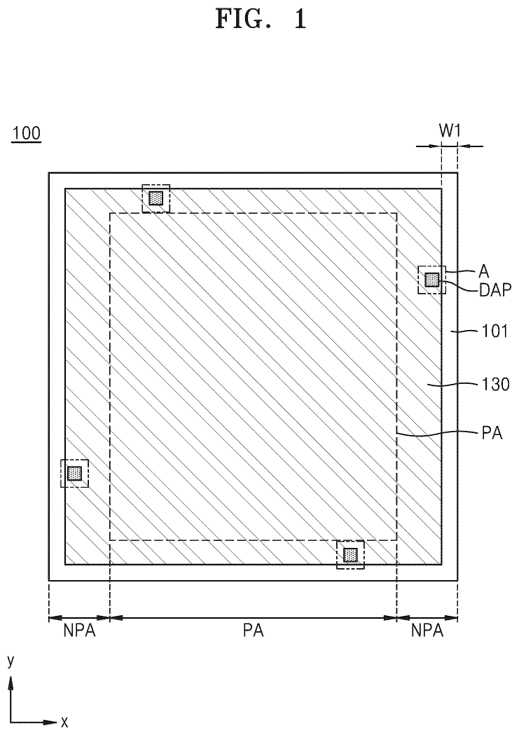

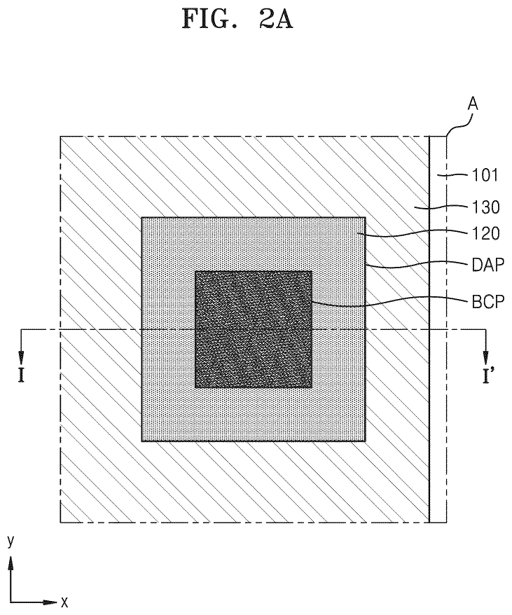

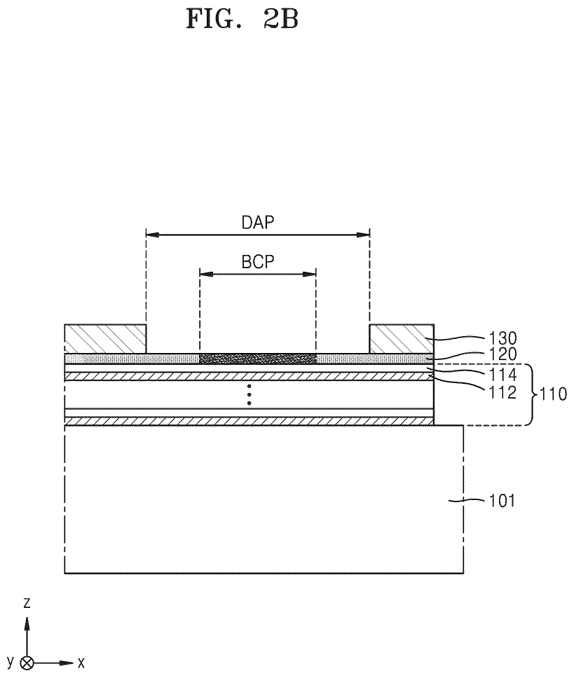

FIG. 1 is a plan view of an extreme ultra-violet (EUV) mask 100 according to an embodiment, FIG. 2A is a plan view illustrating an enlarged portion A of the EUV mask 100 of FIG. 1, and FIG. 2B is a cross-sectional view taken along line I-I′ of FIG. 2A.

Referring to FIGS. 1 to 2B, the EUV mask 100 of the present disclosure may include a substrate 101, a reflective multilayer 110, a capping layer 120, and an absorption layer 130. As can be seen in FIG. 1, the substrate 101, the reflective multilayer 110, the capping layer 120, and the absorption layer 130 may have a rectangular shape in a plan view. In some cases, the reflective multilayer 110, the capping layer 120, and the absorption layer 130 may have different sizes. However, according to some embodiments, the reflective multilayer 110, the capping layer 120, and the absorption layer 130 may have substantially the same size.

In some cases, substrate 101 may have the largest size among the reflective multilayer 110, the capping layer 120, and the absorption layer 130. Accordingly, an upper surface of the substrate 101 may be exposed in a rectangular frame shape in an outer portion of the substrate 101. A first width WI of an exposed portion of the substrate 101 may be, for example, 1.0 mm or more. Here, the first width WI may be defined in a direction perpendicular to a direction of extension of the exposed portion of the substrate 101. For example, in FIG. 1, in the case of upper and lower sides extending in the x direction, the first width WI may be defined in the y direction, and in the case of left and right sides extending in the y direction, the first width WI may be defined in the x direction. In addition, the first width WI is not limited to the provided numerical range.

The substrate 101 may include a low thermal expansion material (LTEM) material. In some cases, the substrate 101 may include a material having a low coefficient of thermal expansion (CTE). For example, the substrate 101 may include glass, silicon (Si), quartz, or the like. However, a material of the substrate 101 is not limited thereto and any other material having a low coefficient of thermal expansion may be used.

According to an embodiment, a transfer region PA and a non-transfer region NPA may be defined on the substrate 101. As shown in FIG. 1, the transfer region PA may be located in the center and the non-transfer region NPA may be located to surround the transfer region PA. Here, the transfer region PA may refer to a region in which patterns to be transferred onto a wafer through an exposure process are located. The patterns to be transferred onto the wafer may be formed on the absorption layer 130. Additionally, the absorption layer 130 may also be divided into a transfer region PA and a non-transfer region NPA to correspond to the definition of the transfer region PA and the non-transfer region NPA of the substrate 101. Accordingly, patterns to be transferred on the wafer may be disposed in the transfer region PA of the absorption layer 130.

In some cases, the reflective multilayer 110 may be disposed on the substrate 101. The reflective multilayer 110 may reflect light incident on the reflective multilayer 110, for example, EUV rays. The reflective multilayer 110 may include a Bragg reflector. EUV rays are used for an optical lithography technology in a semiconductor device fabrication to make integrated circuits (ICs). The lithography technology or EUV lithography uses extreme ultraviolet (EUV) wavelengths near 13.5 nm, using a laser-pulsed tin droplet plasma to generate a pattern using a reflective photomask to expose a substrate covered by photoresist.

An EUV photomask works by reflecting light using multiple alternating layers of molybdenum and silicon. For example, an EUV mask may include 40 alternating silicon and molybdenum layers. The multilayers reflect the extreme ultraviolet light based on Bragg diffraction. In some cases, the reflectance is a function of incident angle and wavelength with long wavelengths reflecting near normal incidence and short wavelengths reflecting away from normal incidence. The pattern is defined in a tantalum-based absorbing layer over the multilayer.

Bragg's law provides angles for coherent scattering of waves from a large crystal lattice. The law encompasses the superposition of wave fronts scattered by lattice planes resulting in a relation between wavelength and scattering angle. In some examples, a relationship between the wavevector transfer with respect to the crystal lattice may be developed.

Bragg diffraction occurs when a radiation of a certain wavelength comparable to atomic spacings is scattered in a specular manner (i.e., mirror-like reflection) by the atoms of a crystalline system and undergoes constructive interference. In case of a crystalline solid, the waves are scattered from lattice planes separated by a particular distance between successive layers of atoms. In case the scattered waves interfere constructively, they remain in phase. The waves are reflected only when they strike the surface at a definite angle. The effect of the constructive or destructive interference intensifies due to the cumulative effect of reflection in successive crystallographic planes of the crystalline lattice leading to Bragg's law, which describes the condition on a glancing angle for strong constructive interference.

According to the EUV mask 100 of the present embodiment, the reflective multilayer 110 may have a multilayer structure in which two types of material layers (e.g., first material layer 112 and second material layer 114) are alternately stacked in several layers. Thus, the reflective multilayer 110 may include a first material layer 112 and a second material layer 114 that are alternately stacked. Accordingly, the second material layer 114 may be located between a pair of adjacent first material layers 112, and similarly, the first material layer 112 may be located between a pair of adjacent second material layers 114. In the EUV mask 100 of an example embodiment, each of the first material layer 112 and the second material layer 114 may be stacked for about 40 to 60 layers. However, the number of layers of each of the first material layer 112 and the second material layer 114 is not limited thereto and any other suitable numerical range may be implemented.

Here, the first material layer 112 may be a low refractive index layer and the second material layer 114 may be a high refractive index layer. Accordingly, the second material layer 114 may have a refractive index higher than that of the first material layer 112. For example, the first material layer 112 may include molybdenum (Mo) and the second material layer 114 may include silicon (Si). However, materials of the first material layer 112 and the second material layer 114 are not limited thereto and any other materials having different refractive index may be used. In the EUV mask 100 of the present embodiment, the first material layer 112, which is a low refractive index layer, may be disposed on the lowermost portion of the reflective multilayer 110 and the second material layer 114, which is a high refractive index layer, may be disposed on the uppermost portion of the reflective multilayer 110.

The capping layer 120 may be disposed on the reflective multilayer 110. The capping layer 120 may prevent damage to the reflective multilayer 110 and reduce surface oxidation of the reflective multilayer 110. In the EUV mask 100 of the present embodiment, the capping layer 120 may cover an upper surface of the second material layer 114, for example, Si, to prevent the second material layer 114 from being oxidized. For example, the capping layer 120 may include ruthenium (Ru). However, the material of the capping layer 120 is not limited to Ru. In some cases. the capping layer 120 may be optional and hence capping layer 120 may be omitted.

The absorption layer 130 may be disposed on the capping layer 120. If the capping layer 120 is omitted, the absorption layer 130 may be directly disposed on the reflective multilayer 110, for example, the second material layer 114. The absorption layer 130 may be divided into a central transfer region PA and an outer non-transfer region NPA. As described with respect to substrate 101, absorption patterns to be transferred onto the wafer through an exposure process may be disposed in the transfer region PA.

The EUV mask 100 of the present disclosure may be an EUV blank mask or an EUV complete mask. The EUV blank mask may refer to a mask before an absorption pattern is formed, that is, before exposure, and may not include a photo-resist (PR) layer on the absorption layer 130. The EUV complete mask, as a concept relative to the EUV blank mask, may include an absorption pattern and a photo-resist (PR) layer in the absorption layer 130.

The absorption layer 130 may include a material that absorbs light incident on the absorption layer 130, for example, EUV rays. Accordingly, EUV rays incident on the absorption layer 130 may not reach the capping layer 120 or the reflective multilayer 110. The absorption layer 130 may include, for example, TaN, TaHf, TaHIN, TaBSi, TaBSIN, TaB, TaBN, TaSi, TaSIN, TaGe, TaGEN, TaZr, TaZrN, or combinations thereof. However, the material of the absorption layer 130 is not limited to the above materials.

In some cases, EUV rays incident on the capping layer 120 exposed through an open region of the absorption layer 130 may pass through the capping layer 120 and reach the reflective multilayer 110. In addition, EUV rays may be reflected by the reflective multilayer 110 and may be irradiated onto the wafer to be exposed. Accordingly, the pattern transferred onto the wafer may correspond to a shape of an open region of the absorption layer 130.

As shown in FIG. 1, in the absorption layer 130, a defect avoidance pattern (DAP) may be formed in the non-transfer region NPA of the absorption layer 130. The DAP may be disposed at an edge region on each of the four sides of the absorption layer 130. The four DAPs may be in a rotationally symmetric relationship with respect to the center point. In some examples, among the four DAPs, two DAPs facing each other based on the center point may be located in point-symmetrical positions based on the center point. Also, a DAP may overlap another adjacent DAP by 90° rotation about the center point.

According to some embodiments of the present disclosure, the four DAPs are formed in the EUV mask 100 to open a beam calibration point (BCP) located in any one of the edge regions of the four sides of the absorption layer 130.

In some examples, an EUV blank mask inspection for inspecting a reflective multilayer may be performed before forming the absorption layer 130 during a process of manufacturing an EUV mask. In some cases, an EUV blank mask inspection may be referred to as blank inspection. Thus, a process of scanning the reflective multilayer 110 with a multi-laser beam to determine whether there are defects in the reflective multilayer 110 may be performed before forming the absorption layer 130. Additionally, beam calibration, such as autofocusing (AF), or the like may be performed at a preset point (i.e., BCP) when starting the blank inspection. Accordingly, the BCP may refer to a point at which a high-power laser beam is irradiated onto the capping layer 120 or the reflective multilayer 110 for beam calibration.

Here, the BCP may be defined on the reflective multilayer 110 when the capping layer 120 is omitted on the reflective multilayer 110. In some cases, during the beam calibration process, oxidation may be accelerated on at least a portion of the capping layer 120 at the BCP portion due to the high-power laser beam. Referring to FIGS. 2A and 2B, the BCP is indicated by a hatching that is different from that of the reflective multilayer. The BCP may include substantially the same material layer as that of the capping layer 120 or the reflective multilayer 110.

Although the x and y coordinates of the BCP are known, in case the EUV blank mask or the EUV complete mask are rotated after the absorption layer 130 is formed on the capping layer 120 or the reflective multilayer 110, the BCP cannot be specified as one position. Therefore, by forming the DAPs at four positions corresponding to 90° rotational symmetry, the BCP may be open at the DAP of one of the four positions.

In some cases, rotation of the EUV blank mask or the EUV complete mask may be performed for mask defect avoidance (MDA) or the like. MDA is referred to as multilayer defect avoidance. Here, MDA may refer to a technology of avoiding a defect by using an absorption layer when a defect that cannot be repaired exists in the EUV mask. Thus, MDA may refer to technology of linearly moving or rotating the EUV mask such that a defect is located in a portion in which the absorption layer is present, that is, in a dark pattern portion, so that the defect is not transferred to the wafer. For example, a defect of the reflective multilayer below the dark pattern cannot be transferred to the wafer during an EUV exposure process because EUV rays are absorbed in the dark pattern portion. Thus, by linearly moving or rotating the EUV mask to move the defect of the reflective multilayer to the portion of the dark pattern, the defect may not appear.

The DAP may include one through-hole structure penetrating the absorption layer 130. A horizontal cross-section of the DAP may have a quadrangular shape, as shown in FIG. 2A. However, the shape of the horizontal cross-section of the DAP is not limited to a quadrangular shape. For example, according to some embodiments, the horizontal cross-section of the DAP may comprise various shapes, e.g., a circle, an ellipse, or any polygon. In some cases, the DAP may have a single pattern structure because the DAP includes one through-hole. The DAP may expose the BCP of the capping layer 120 or the reflective multilayer 110 through the through-hole structure.

In some cases, the occurrence of a blister defect in the exposure process using the EUV mask 100 may be minimized based on exposing the BCP through the DAP in the EUV mask 100. Here, the blister defect may refer to a defect in which a portion between the capping layer 120 and the absorption layer 130 is lifted. In some examples, impurities, for example, carbon-containing impurities, may be formed on the surface of the EUV mask during the EUV exposure process. Hydrogen (H₂) may be supplied on the EUV mask to remove these impurities. However, hydrogen (H₂) may be dissociated by EUV rays, and dissociated hydrogen atoms (H*) may penetrate into the EUV mask and penetrate between the capping layer 120 and the absorption layer 130.

Additionally, hydrogen atoms (H*) penetrating between the capping layer 120 and the absorption layer 130 may recombine to accumulate hydrogen (H₂) between the capping layer 120 and the absorption layer 130 leading to a lifted portion between the capping layer 120 and the absorption layer 130. According to embodiments of the present disclosure, hydrogen (H₂) may be discharged through the DAP and a blister defect may be effectively prevented because the DAP exposing the BCP is formed in the EUV mask 100. Accordingly, the reliability and durability of the EUV mask 100 may be significantly improved.

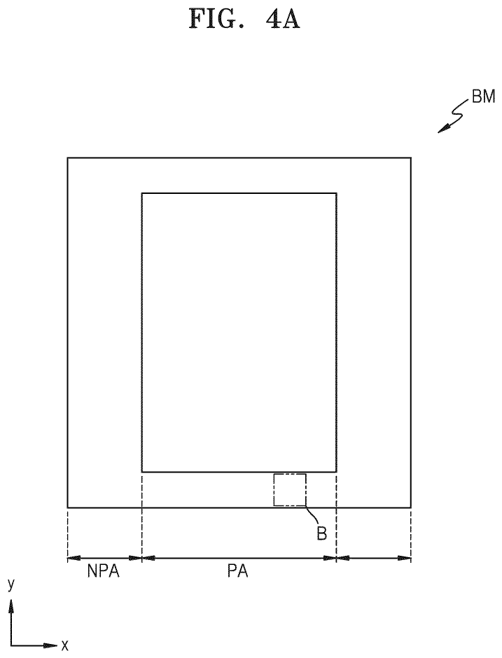

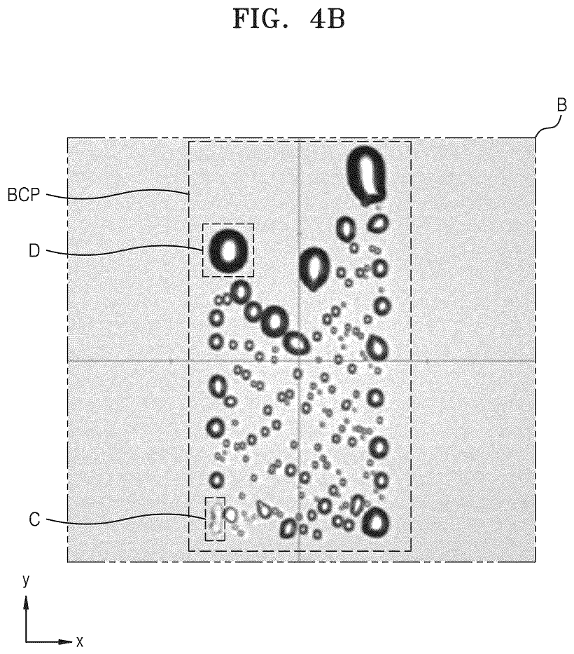

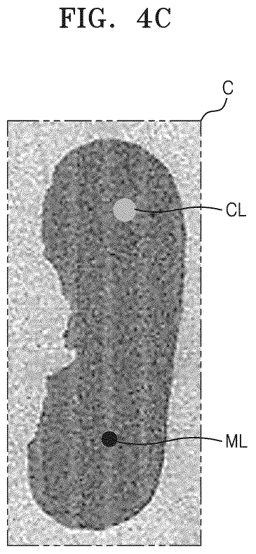

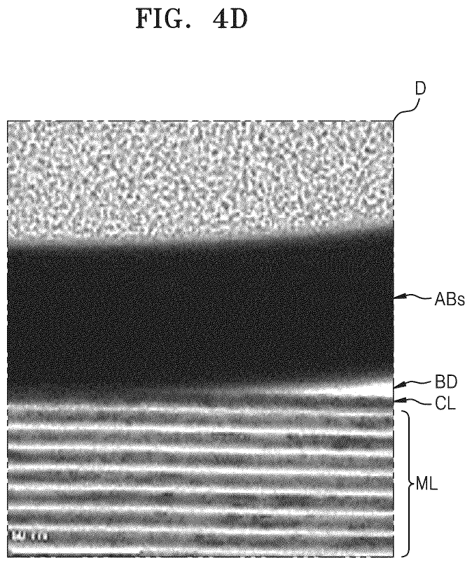

In some cases, the blister defect prevented by the EUV mask 100 of the present disclosure may be slightly different from a general blister defect of an EUV mask. Thus, the general blister defect of the EUV mask is caused by hydrogen (H₂) accumulated between a capping layer and a reflective multilayer, whereas the blister defect prevented in the EUV mask 100 of the present embodiment is caused by hydrogen (H₂) accumulated between the capping layer 120 and the absorption layer 130. However, in case the capping layer is omitted, the blister defect may occur between the absorption layer 130 and the reflective multilayer 110. The blister defect to be prevented by the EUV mask 100 of the present disclosure is described in more detail with reference to FIGS. 4A to 4D below.

According to an embodiment of the present disclosure, the DAP may have a larger area than that of the BCP in the EUV mask 100. Here, the area may be defined based on an upper surface of the capping layer 120 or the reflective multilayer 110. The area of the BCP may correspond to the size of a laser beam performing beam calibration, that is, the area of a cross-section perpendicular to an optical axis of the laser beam.

For example, in case the area of the BCP is about 200×400 μm², the area of DAP may be at least 400×400 μm². In some examples, DAP may have an area of at least 400×400 μm² considering the rotation of the blank EUV mask or EUV complete mask. However, the areas of the BCP and the DAP are not limited thereto and other suitable values for the areas of BCP and DAP may be used. As shown in FIGS. 2A and 2B, the BCP may be located in the DAP on an upper surface of the capping layer 120 or the reflective multilayer 110. However, according to some embodiments, only a portion of the BCP may be located inside the DAP.

According to some embodiments, the DAP may be located to prevent a blister defect from occurring in a BCP portion during the EUV exposure process in the EUV mask 100. That is, when the DAP exposing the BCP is formed, hydrogen H₂ accumulated between the absorption layer 130 and the capping layer 120 corresponding to the BCP portion may be discharged through the DAP which effectively prevents blister defects. Accordingly, the reliability and durability of the EUV mask 100 may be significantly improved.

In some cases, patterns or holes may be formed in the transfer region PA of the absorption layer to prevent general blister defects of the EUV mask. The patterns or holes are referred to as anti-blister pattern (ABP) or anti-blister pattern hole (ABPH). Here, ABPH refers to a hole formed in the absorption layer and ABP refers to a pattern formed through the ABPH. However, hereinafter, the ABPH and the ABP are collectively referred to as an ABP. In some cases, the ABP may have a size smaller than the minimum line width defined by the resolution of the EUV process because the ABP should not be transferred to the wafer. In addition, there is a limit in that the ABP cannot be formed in the outermost quadrangular frame region of the absorption layer because the ABP is generally formed using an electron beam (E-beam). Here, the outermost quadrangular frame region of the absorption layer may include ground regions in which an electron beam exposure apparatus is grounded.

According to an embodiment, the DAP may be formed in the non-transfer region NPA of the EUV mask 100. Accordingly, the DAP may not be transferred to a wafer in the EUV exposure process and may have a size equal to or greater than the minimum line width defined by resolution of an EUV exposure apparatus. That is, the DAP may not be limited by the resolution of the EUV exposure apparatus. Further, the DAP in the EUV mask 100 may be formed through an exposure process using a laser beam, a repair process using a laser beam, an electron beam, nano-machining, or the like, an imprint process, or a directed self-assembly (DSA) process, without being limited to the electron beam exposure process. Directed self-assembly (DSA) is a directed assembly process that uses block co-polymer morphology to create lines, space and hole patterns, thereby facilitating an accurate control of the feature shapes. For example, the DSA is not a standalone process and is integrated with a manufacturing process to mass-produce micro and nano structures used in semiconductor devices.

Additionally, the DAP may be formed through a single patterning process or a multiple patterning process, such as double patterning or quadruple patterning. Single patterning or multiple patterning may be performed through an exposure process using a laser beam or electron beam, a repair process using a laser beam, electron beam, nano-machining, or the like, an imprint process, or a DSA process.

In some cases, a single patterning process creates patterns on semiconductor devices with tight pitches using a single EUV lithographic exposure. In case of multiple patterning, the original mask shapes are relaxed and divided between two or more masks. Further, each mask is printed separately, eventually imaging the entire set of originally-drawn shapes onto the wafer. That is, the multiple patterning process requires three exposures to process the critical metal layers.

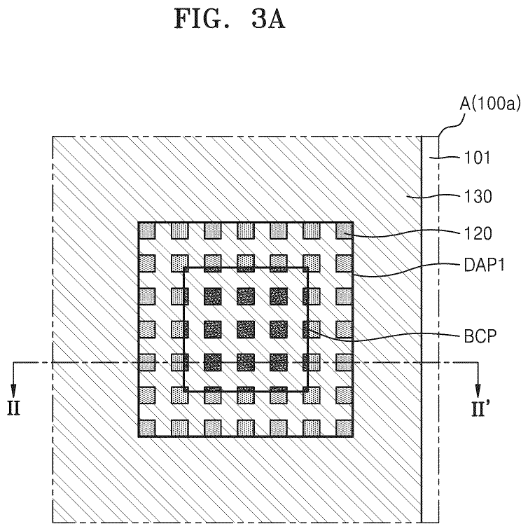

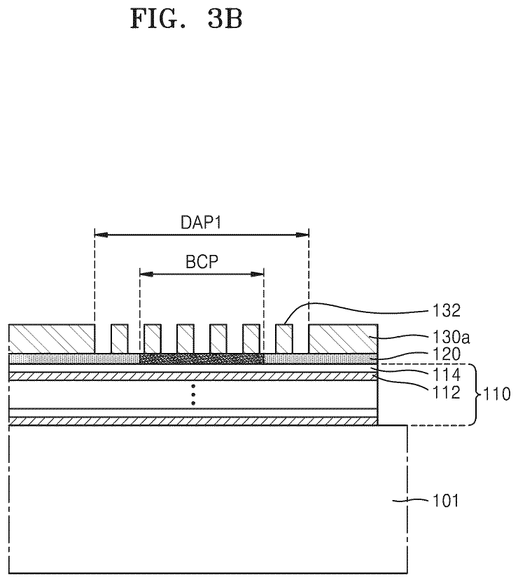

FIG. 3A is an enlarged plan view of portion A of the EUV mask of FIG. 1, and FIG. 3B is a cross-sectional view taken along line II-II′ of FIG. 3A. Details of the EUV mask are provided with reference to FIGS. 1-2B and repeated descriptions are omitted.

Referring to FIGS. 3A and 3B, an EUV mask 100a of the present embodiment may be different from the EUV mask 100 of FIG. 2A in a structure of a defect avoidance pattern DAP1. In some cases, in the EUV mask 100a of the present embodiment, the defect avoidance pattern DAP1 may be located in the edge portion of each of the four sides of an absorption layer 130a, like the DAP of the absorption layer 130 of the EUV mask 100 of FIG. 2A. In addition, the four defect avoidance patterns DAP1 may be in a rotationally symmetric relationship with respect to the center point. Thus, among four defect avoidance patterns DAP1, two defect avoidance patterns DAP1 facing each other with respect to the center point may be located in point-symmetrical positions based on the center point. Additionally, any one defect avoidance pattern DAP1 may overlap another adjacent defect avoidance pattern DAP1 by 90° rotation about the center point. The BCP may be exposed from any one of the four defect avoidance patterns DAP1 in the EUV mask 100a of the present embodiment.

The defect avoidance pattern DAP1 may include a plurality of micro-holes penetrating the absorption layer 130a in the EUV mask 100a of the present embodiment. The micro-holes may be arranged in a two-dimensional (2D) array structure in the DAP1. The micro-holes are defined by lattice lines 132 of the absorption layer 130a and a horizontal cross-section of each of the micro-holes may have a quadrangular shape as shown in FIG. 3A. However, the shape of the horizontal cross-section of the micro-hole is not limited to a quadrangular shape. For example, according to some embodiments, the horizontal cross-section of the micro-hole may have various shapes, such as a circle, an ellipse, a polygon, etc. The defect avoidance pattern DAP1 may have an array pattern structure because the defect avoidance pattern DAP1 includes the micro-holes arranged in the 2D array structure. The defect avoidance pattern DAP1 may expose the BCP of the capping layer 120 or the reflective multilayer 110 through the array pattern structure. In some cases, the BCP may be exposed only in the micro-holes and may not be exposed in a portion of grating lines 132 of the absorption layer 130a defining the micro-holes.

The defect avoidance pattern DAP1 may have an area larger than that of the BCP in the EUV mask 100a of the present embodiment. Here, the area of the defect avoidance pattern DAP1 may be defined on the upper surface of the capping layer 120 or the reflective multilayer 110 and may be defined by the outer side of each of the outermost micro-holes. As seen in FIG. 3A, the defect avoidance pattern DAP1 may have a roughly quadrangular shape by the outer side of each of the outermost micro-holes and the area of the quadrangle may correspond to the area of the defect avoidance pattern DAP1. Additionally, the area of the quadrangle of the defect avoidance pattern DAP1 may be larger than the area of the BCP. Further, as shown in FIG. 3A, the BCP on the upper surface of the capping layer 120 or the reflective multilayer 110 may be located inside the quadrangle of the defect avoidance pattern DAP1. The BCP may be exposed only in the micro-holes because the defect avoidance pattern DAP1 has an array pattern structure including the micro-holes.

The micro-holes in the defect avoidance pattern DAP1 may have a very small size. Here, the size of the micro-hole may be defined by a width, a diameter, a minor axis, and the like. In some cases, when the horizontal cross-section of the micro-hole is a polygon, the size of the micro-hole may be defined as a width between opposite sides. In some cases, when the horizontal cross-section of the micro-hole is a circle, the size of the micro-hole may be defined as a diameter. In some cases, when the horizontal cross-section of the micro-hole is elliptical, the size of the micro-hole may be defined as a minor axis. However, the size of the micro-hole is not limited to the above definitions.

According to some examples, the size of the micro-hole may be 1 μm or less. The horizontal cross-section of the micro-hole may have a quadrangular shape and the width of the micro-hole may be 1 μm or less in the EUV mask 100a of the present embodiment. However, the width of the micro-hole is not limited thereto and the width of the micro-hole may be different from the aforementioned numerical range. As shown in FIG. 3A, the micro-holes may be arranged in a 2D array structure in the defect avoidance pattern DAP1. Thus, the micro-holes may be arranged at regular intervals or pitches in the x and y directions in the defect avoidance pattern DAP1. For example, the micro-hole may have an interval of 4 μm or less from the micro-holes adjacent thereto in the x and y directions. Also, assuming that the micro-hole has a width of 1 μm or less, the micro-holes may be arranged with a pitch of 5 μm or less in the x direction and the y direction. However, the interval or pitch of the micro-holes is not limited thereto and the interval or pitch of the micro-holes may be different from the above numerical ranges. In some examples, when the defect avoidance pattern DAP1 has an area of 500×500 μm² or more and the micro-holes have a pitch of about 5 μm, 100 or more micro-holes may be arranged in the x direction and the y direction, respectively, in the defect avoidance pattern DAP1. However, the number of micro-holes arranged in the defect avoidance pattern DAP1 is not limited to the provided numerical values and the area of the defect avoidance pattern DAP1, the width, and pitch of the micro-holes, etc. may be variously changed.

FIGS. 4A to 4D are plan views and photographs showing defects of an EUV mask BM of a comparative example. FIG. 4B is an image obtained from a scanning electron microscope (SEM) illustrating an enlarged portion of region B in FIG. 4A. FIG. 4C is an image obtained from a SEM illustrating an enlarged portion of region C of FIG. 4B. FIG. 4D is an image obtained from a transmission electron microscope (TEM) illustrating an enlarged portion of region D of FIG. 4B.

A scanning electron microscope (SEM) is a subset of electron microscopes that produces images of a sample by scanning the surface with a focused beam of electrons of relatively low energy as an electron probe that is scanned in a regular manner over the specimen. The electrons interact with atoms in the sample, producing various signals that contain information about the surface topography and composition of the sample.

A transmission electron microscopy (TEM) refers to a technique comprising a beam of electrons that is transmitted through a specimen to form an image. In some cases, TEM is performed for specimens having a thickness of less than 100 nm. An image is formed from the interaction of the electrons with the sample as the beam is transmitted through the specimen. The image is then magnified and focused onto an imaging device.

Referring to FIGS. 4A to 4D, the EUV mask BM of the comparative example may include a transfer region PA in the center portion and a non-transfer region NPA in an outer portion. A BCP may be located in the portion B of FIG. 4A. A plurality of blister defects appear in the BCP portion in the enlarged portion B of the SEM photograph of FIG. 4B. In addition, the blister defects increase in the y direction. As shown in FIG. 4B, a rectangular portion indicated by the dashed line may correspond to the BCP.

As shown in FIG. 4C, the image obtained from SEM illustrating an enlarged portion of region C indicates a state in which blister bursts. A portion indicated by CL in FIG. 4C represents a region in which the blister bursts such that the capping layer is exposed and a portion indicated by ML indicates a region in which the blister bursts and even the reflective multilayer is exposed. In addition, vertical stripes in the SEM image indicate the periodicity of multi-laser beams during blank inspection. The enlarged TEM image of FIG. 4D for the portion D indicates that a blister defect BD occurs between the capping layer CL and the absorption layer ABs on the reflective multilayer ML resulting in delamination of the absorption layer ABs from the capping layer CL.

According to some embodiments, the vertical stripes may be caused by a high-power laser beam during a beam calibration process of the blank inspection in the enlarged SEM photograph of FIG. 4C. That is, thermal oxidation of the capping layer CL of Ru may be promoted by a high-power laser beam during the beam calibration process. For example, an increase of up to 18% of the oxide layer at the BCP compared to other regions has been seen. As a result, the blister defect BD between the capping layer CL and the absorption layer ABs is caused as the oxidation layer generated by the beam calibration process promotes trapping/bonding of hydrogen atoms. Accordingly, the defect avoidance patterns DAPs and DAP1 exposing the BCP are formed in the EUV masks 100 and 100a, thereby effectively preventing blister defects caused by the beam calibration process of the blank inspection.

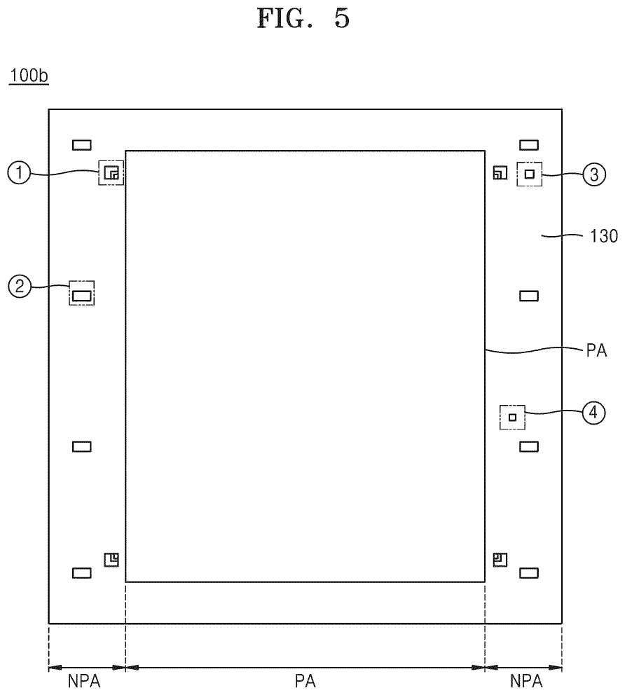

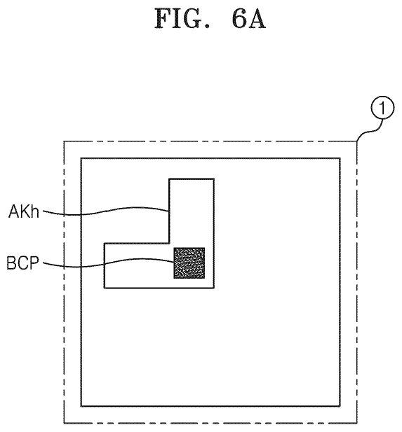

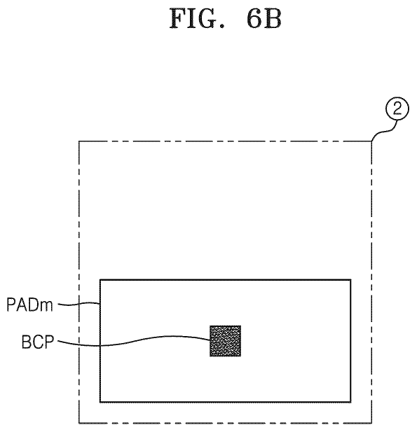

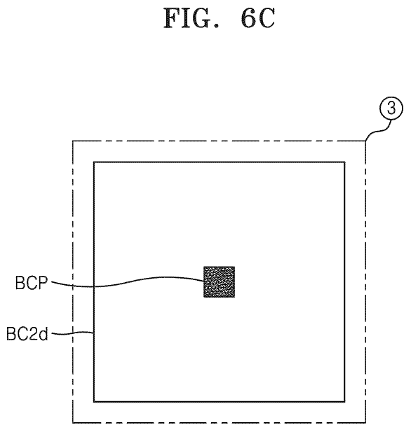

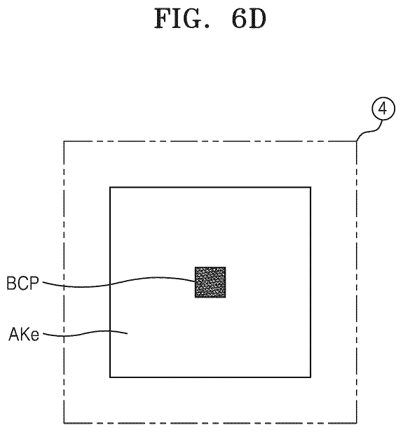

FIG. 5 is a plan view of an EUV mask 100b according to an embodiment of the present disclosure. FIGS. 6A to 6D are plan views illustrating enlarged portions 1 to 4 of FIG. 5. Repeated descriptions with reference to FIGS. 1 to 4D are briefly provided or omitted for brevity.

Referring to FIGS. 5 to 6D, the EUV mask 100b of the present embodiment may be different from the EUV masks 100 and 100a of FIGS. 1 to 3A such that a separate DAP is not formed and the BCP is exposed using a process pattern essentially and/or commonly formed in the EUV mask 100b. Here, the process pattern of the EUV mask may include an inspection pattern, an alignment pattern, a measurement pattern, a monitoring pattern, an EUV scanning pattern, etc. used in an EUV mask manufacturing process or an exposure process using an EUV mask. For example, the process pattern of the EUV mask may include an alignment key when manufacturing the EUV mask 100b, an EUV reflectance (EUVR) measurement pad, various process/facility monitoring keys, and various keys or marks used in an EUV scanner. In some cases, the process pattern of the EUV mask may be located in the non-transfer region of the absorption layer.

The process pattern in the EUV mask 100b may be disposed in the non-transfer region NPA of the absorption layer 130. In some cases, the size of the process pattern used to expose the BCP may be larger than the size of the BCP. As a result, the occurrence of blister defects in the EUV mask 100b may be prevented by locating the BCP below the large-sized process pattern.

In addition, the EUV mask 100b may include the substrate 101, the reflective multilayer 110, the capping layer 120, and the absorption layer 130, similar to the EUV mask 100 of FIG. 1. Additionally, the process pattern may be formed by patterning the absorption layer 130. Accordingly, the process pattern may expose the lower capping layer 120 or the reflective multilayer 110. FIGS. 6A to 6D are plan views showing shapes of representative process patterns.

FIG. 6A shows an inspection alignment key AKh that has an ‘L’ shape and that exposes the capping layer 120 or the reflective multilayer 110. A BCP is displayed together for size comparison in a central region. For example, when the BCP has a size of 400×400 μm², the inspection alignment key AKh may have a width of 600 μm or more. However, the sizes of the BCP and the inspection alignment key AKh are not limited thereto and the sizes of the BCP and the inspection alignment key Akh may be different from the provided values.

FIG. 6B shows an EUVR measurement pad PADm which has a rectangular shape and exposes the capping layer 120 or the reflective multilayer 110. The EUVR measurement pad PADm is displayed with a BCP for size comparison. For example, when the BCP has a size of 400×400 μm², a width of the EUVR measurement pad PADm in a width direction may be 2500 μm or more. However, the sizes of the BCP and the EUVR measurement pad PADm are not limited thereto and the sizes of the BCP and the EUVR measurement pad PADm may be different from the provided values.

FIG. 6C shows a 2D barcode BC2d. The 2D barcode BC2d has a quadrangular shape, and various patterns may be formed inside the quadrangle. Accordingly, the capping layer 120 or the reflective multilayer 110 may be exposed by various patterns inside the quadrangle. The 2D barcode BC2d is displayed with a BCP for size comparison. For example, when the BCP has a size of 400×400 μm², a length of one side of the quadrangle of the 2D barcode BC2d may be 2400 μm or more. However, the sizes of the BCP and the 2D barcode BC2d are not limited thereto and the sizes of the BCP and the 2D barcode BC2d may be different from the provided values.

Finally, FIG. 6D shows an exposure alignment key AKe which may have a quadrangular shape and expose the capping layer 120 or the reflective multilayer 110. The exposure alignment key AKe is displayed together with a BCP for size comparison. For example, when the BCP has a size of 400×400 μm², a length of one side of the quadrangle of the exposure alignment key AKc may be 1400 μm or more. However, the sizes of the BCP and the exposure alignment key AKe are not limited thereto and the sizes of the BCP and the exposure alignment key AKe may be different from the provided values.

Accordingly, a separate DAP is not formed in the EUV mask 100b and a BCP may be exposed using a process pattern essential/common to the EUV mask 100b. Therefore, the EUV mask 100b of the present embodiment prevents resource waste, such as additional processes/equipment, and turn around time (TAT) loss during the manufacturing process of the EUV mask 100b, while effectively avoiding the occurrence of blister defects, thereby contributing to optimization of the manufacturing process.

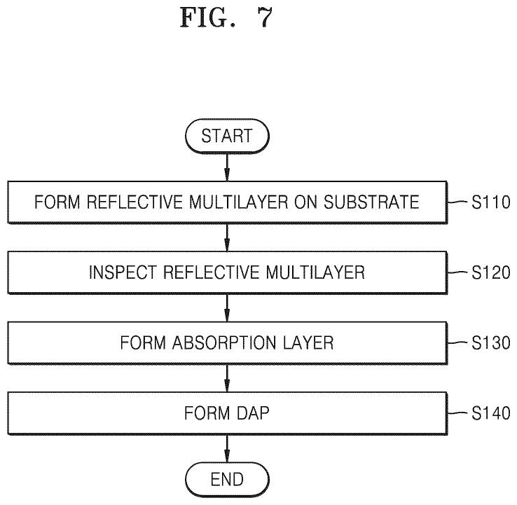

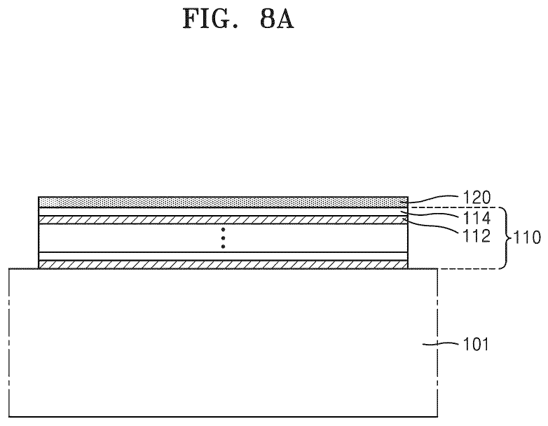

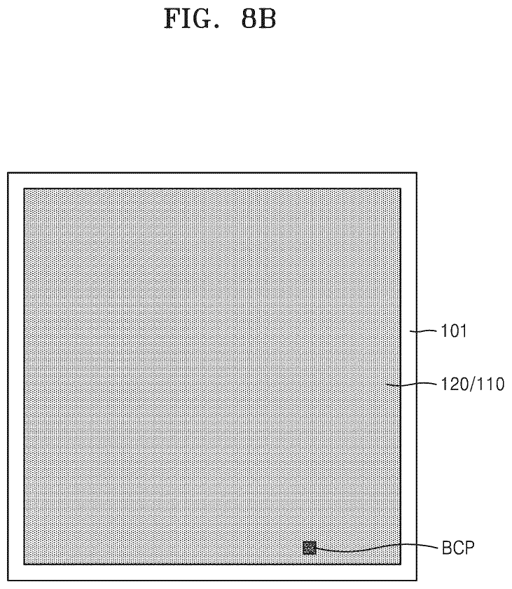

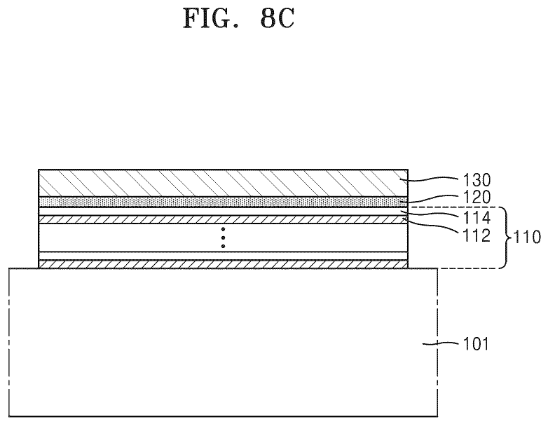

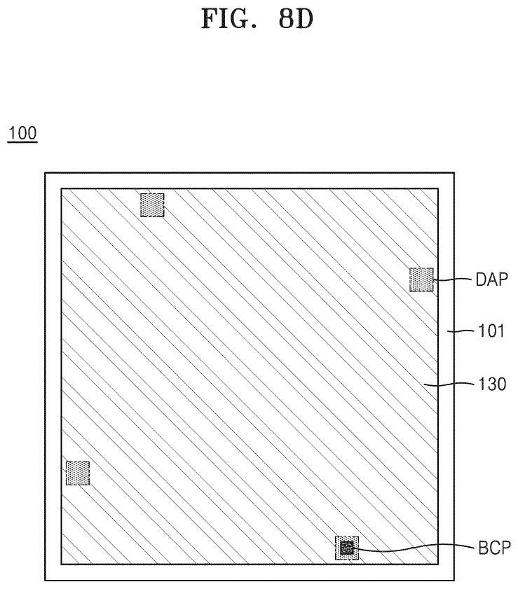

FIG. 7 is a flowchart schematically illustrating a manufacturing method of the EUV mask 100 of FIG. 1. FIGS. 8A to 8D are cross-sectional views and plan views of the EUV mask 100 corresponding to operations of the method of manufacturing the EUV mask 100 of FIG. 7. Descriptions are given with reference to FIGS. 1 to 2B together, and repeated descriptions with reference to FIGS. 1 to 6D are briefly provided or omitted for brevity.

Referring to FIGS. 7 and 8A, first, the reflective multilayer 110 is formed on the substrate 101 (S110) in the manufacturing method of an EUV mask. The substrate 101 may include an LTEM material. For example, the substrate 101 may include glass, Si, quartz, or the like. The substrate 101 may have a size larger than the reflective multilayer 110.

The reflective multilayer 110 may have a multilayer structure in which tens of two types of first and second material layers 112 and 114 are alternately stacked. Here, the reflective multilayer 110 may include a first material layer 112 that is a low refractive index layer and a second material layer 114 that is a high refractive index layer. For example, the first material layer 112 may include Mo and the second material layer 114 may include Si. However, the materials of the first material layer 112 and the second material layer 114 are not limited thereto and the reflective layer may include any other materials with different refractive index.

The capping layer 120 may be further formed on an upper surface of the reflective multilayer 110 during the formation of the reflective multilayer 110 (S110). The capping layer 120 may be formed to prevent damage to the reflective multilayer 110 and surface oxidation of the reflective multilayer 110. In the method of manufacturing an EUV mask, the capping layer 120 may cover the upper surface of the second material layer 114 of Si to prevent the second material layer 114 from being oxidized. For example, the capping layer 120 may include Ru. However, the material of the capping layer 120 is not limited to Ru. The capping layer 120 may be optional. Accordingly, in some embodiments, the capping layer 120 may be omitted.

As shown in FIG. 8A, the reflective multilayer 110 and the capping layer 120 may have a size less than the substrate 101. Although not shown, the reflective multilayer 110 may have a size less than the substrate 101 and may include an edge-inclined region at an edge side. The capping layer 120 may extend onto the substrate 101, while covering the edge-inclined region of the reflective multilayer 110. Accordingly, the size of the capping layer 120 may be substantially similar to that of the substrate 101 after forming the capping layer 120. However, as the edge portions of the capping layer 120 and/or the absorption layer 130 are subsequently removed through an edge trimming process or the like, the edge portion of the substrate 101 may be exposed.

Referring to FIGS. 7 and 8B, after forming the reflective multilayer 110 and the capping layer 120, the reflective multilayer 110 is inspected (S120). That is, EUV blank mask inspection or blank inspection is performed. As described above, the blank inspection is a process of inspecting whether there is a defect in the reflective multilayer 110 and may be performed by scanning the reflective multilayer 110 or the capping layer 120 with a laser beam. For example, 65 multi-laser beams may be used for scanning of the blank inspection. However, laser beams used for scanning are not limited to 65 multi-laser beams.

When performing the blank inspection, first, beam calibration may be performed at a BCP. For example, the BCP may be set to one position. However, according to some embodiments, the BCP may be set to a plurality of positions. As shown in FIG. 8B, a BCP is displayed on a lower edge portion of the reflective multilayer 110 or the capping layer 120.

Referring to FIGS. 7 and 8C, after inspecting the reflective multilayer 110, the absorption layer 130 is formed on the reflective multilayer 110 or the capping layer 120 (S130). That is, the absorption layer 130 may be formed on the capping layer 120 or, if the capping layer 120 is omitted, the absorption layer 130 may be formed on the reflective multilayer 110. In some cases, the absorption layer 130 may be divided into a central transfer region PA and an outer non-transfer region NPA. The absorption layer 130 may include a material that absorbs EUV rays. For example, the absorption layer 130 may include TaN, TaHf, TaHIN, TaBSi, TaBSIN, TaB, TaBN, TaSi, TaSIN, TaGe, TaGEN, TaZr, TaZrN, or combinations thereof. However, the material of the absorption layer 130 is not limited thereto and any other material that can absorb EUV rays may be used.

Referring to FIGS. 7 and 8D, after the formation of the absorption layer 130, the DAP is formed in the non-transfer region NPA of the absorption layer 130 (S140). As shown in FIG. 8D, the DAP may be formed in the edge portion of each of the four sides of the absorption layer 130. The four DAPs may be in a rotationally symmetric relationship with respect to the center point. According to an embodiment, among the four DAPs, two DAPs facing each other with respect to the center point may be located in point-symmetrical positions based on the center point. Also, one DAP may overlap another adjacent DAP by 90° rotation about the center point.

Accordingly, the BCP may be exposed from any one of the four DAPs. For example, in FIG. 8D, the BCP may be exposed in the DAP of the edge portion of the lower side of the absorption layer 130. The area of each of the four DAPs may be larger than the area of the BCP. In addition, the BCP may be located inside one corresponding DAP. In addition, the DAP may have a single pattern structure as shown in FIG. 2A or an array pattern structure as shown in FIG. 3A.

Thereafter, the EUV mask 100 may be completed by forming process patterns required in the non-transfer region NPA of the absorption layer 130 and transfer patterns to be transferred to the wafer in the transfer region PA. The process patterns and transfer patterns may be included in an absorption pattern formed through patterning of the absorption layer 130. According to the method of manufacturing the EUV mask 100 of the present embodiment, the EUV mask 100 in which blister defects are effectively prevented in the EUV exposure process by exposing the BCP through DAPs may be manufactured.

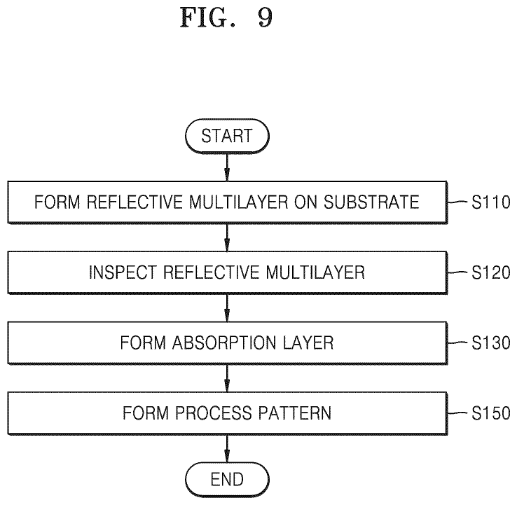

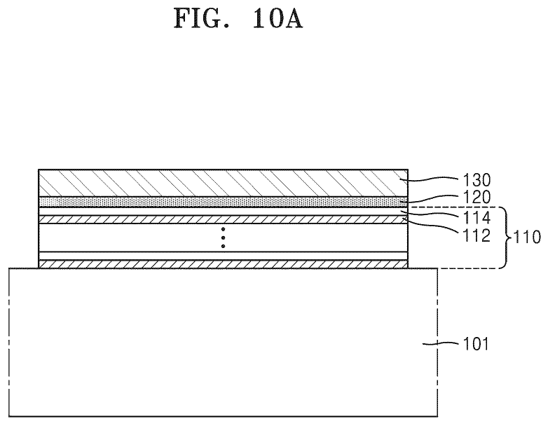

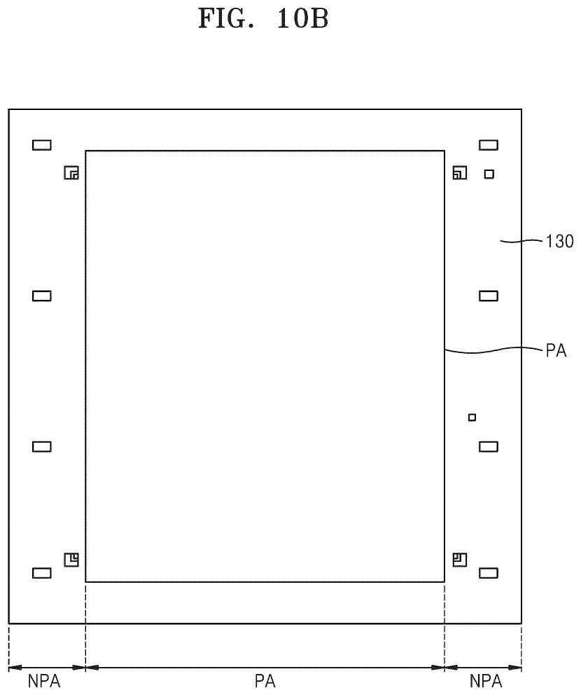

FIG. 9 is a flowchart schematically illustrating a process of a method of manufacturing an EUV mask of FIG. 5, according to an embodiment. FIGS. 10A and 10B are cross-sectional and plan views of an EUV mask corresponding to operations of the method of manufacturing an EUV mask of FIG. 9. Descriptions are given with reference to FIGS. 1, 3A, and 3B together, and repeated descriptions with reference to FIGS. 7 to 8D are briefly provided or omitted.

Referring to FIGS. 9 and 10A, the method of manufacturing an EUV mask of the present embodiment includes forming the reflective multilayer 110 (S110), inspecting the reflective multilayer 110 (S120), and forming the absorption layer 130 which are sequentially performed. Operations S110 to S130 are the same as those described above with reference to FIGS. 7 to 8C.

Referring to FIGS. 9 and 10B, the process pattern is formed in the non-transfer region NPA of the absorption layer 130 (S150). Here, the process pattern may refer to a pattern essentially and/or commonly formed on the EUV mask 100. The process pattern may include, for example, an inspection pattern, an alignment pattern, a measurement pattern, a monitoring pattern, an EUV scan pattern, and the like, which are used in a manufacturing process of an EUV mask or an exposure process using an EUV mask. In some cases, the process pattern may include an alignment key when manufacturing the EUV mask 100b, an EUVR measurement pad, various process/facility monitoring keys, and various keys or marks used in an EUV scanner. Furthermore, transfer patterns may be formed in the transfer region PA during the process of forming the process pattern or before or after the process of forming the process pattern.

During the method of manufacturing the EUV mask 100b of the present embodiment, one of the process patterns may expose the BCP. In addition, the area of the process pattern exposing the BCP may be larger than the area of the BCP. Accordingly, the BCP may be located inside the corresponding process pattern. The BCP may be exposed using the process pattern, without forming a separate DAP in the method of manufacturing the EUV mask 100b of the present embodiment. Therefore, while preventing the occurrence of blister defects, additional processes/equipment and turn around time (TAT) loss may be prevented during the manufacturing process of the EUV mask 100b, thereby contributing to optimization of the manufacturing process.

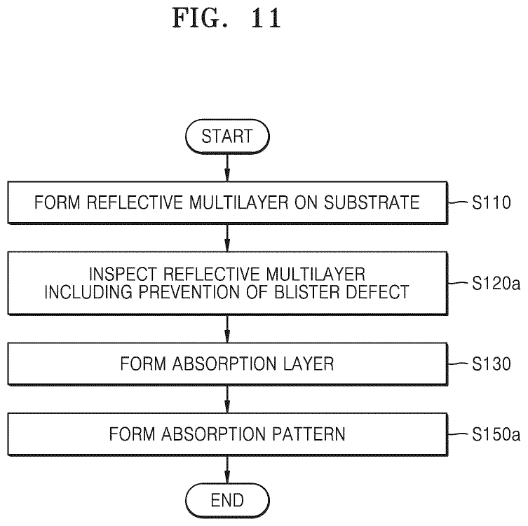

FIG. 11 is a flowchart schematically illustrating a manufacturing method of an EUV mask, according to an embodiment. Descriptions are given with reference to FIGS. 1 to 2B together, and repeated descriptions with reference to FIGS. 7 to 10B are briefly provided or omitted for brevity.

Referring to FIG. 11, first, the reflective multilayer 110 is formed on the substrate 101 (S110) in the method of manufacturing an EUV mask of the present embodiment. The formation of the reflective multilayer 110 (S110) is the same as described above with reference to FIGS. 7 and 8A.

Next, the reflective multilayer 110 is inspected including prevention of blister defects (S120a). That is, EUV blank mask inspection or blank inspection is performed by adding prevention of blister defects. In some cases, the blank inspection may be performed by performing beam calibration at a BCP and then scanning the reflective multilayer 110 or the capping layer 120 with a multi-laser beam. For example, 65 multi-laser beams may be used in the scanning of the blank inspection. However, laser beams used for scanning are not limited to 65 multi-laser beams.

In some cases, during the manufacturing method of an EUV mask, at least one of the following three methods may be further performed in the blank inspection to prevent blister defects. Firstly, when beam calibration is performed, BCPs do not overlap each other. Scanning by multi-laser beams may be performed multiple times and blister defects may be reduced by changing BCPs. Secondly, beam calibration is performed while cooling the EUV mask 100. Thermal oxidation of the BCP portion may be suppressed to reduce blister defects through the cooling. Thirdly, an antioxidant film is formed at the BCP before or after performing beam calibration. Blister defects may be reduced by suppressing oxidation through such an antioxidant film.

After inspecting the reflective multilayer 110, the absorption layer 130 is formed on the reflective multilayer 110 or the capping layer 120 (S130). The forming of the absorption layer 130 (S130) is as described above with reference to FIGS. 7 and 8C.

Thereafter, an absorption pattern is formed on the absorption layer 130 (S150a). The absorption pattern may include process patterns formed in the non-transfer region NPA of the absorption layer 130 and transfer patterns formed in the transfer region PA of the absorption layer 130. By forming the absorption pattern on the absorption layer 130, the EUV mask 100 may be formed.

In addition, during the method of manufacturing the EUV mask of the present embodiment, step S140 of forming the DAP of the manufacturing method of the EUV mask 100 of FIG. 7 or step S150 of forming the process pattern of the method of manufacturing the EUV mask 100b of FIG. 9 may be added. In some cases, step S140 of forming of the DAP in the method of manufacturing the EUV mask 100 of FIG. 7 may be performed before step S150a of forming of the absorption pattern in the absorption layer 130 of the method of manufacturing the EUV mask of the present embodiment. In addition, step S150 of forming of the process pattern of the method of manufacturing the EUV mask 100b of FIG. 9 may be applied when forming the process patterns in the non-transfer region NPA of the absorption layer 130 in step S150a of forming of the absorption pattern of the method of manufacturing the EUV mask of the present embodiment.

Embodiments of the present disclosure include an EUV mask and/or the method of manufacturing the EUV mask for preventing blister defects. In some cases, the method for preventing blister defects in relation to beam calibration of the EUV mask blank inspection have been described. However, the inventive concept is not limited thereto. For example, in relation to the EUV mask and/or manufacturing method thereof, beam calibration may be performed in measurement, inspection, monitoring, etc. using a laser beam, and therefore, the present disclosure may be applied to beam calibration, such as measurement, inspection, monitoring, etc.

While the inventive concept has been particularly shown and described with reference to embodiments thereof, it will be understood that various changes in form and details may be made therein without departing from the spirit and scope of the following claims.

The processes discussed above are intended to be illustrative and not limiting. One skilled in the art would appreciate that the steps of the processes discussed herein may be omitted, modified, combined, and/or rearranged, and any additional steps may be performed without departing from the scope of the invention. More generally, the above disclosure is meant to be exemplary and not limiting. Only the claims that follow are meant to set bounds as to what the present invention includes. Furthermore, it should be noted that the features and limitations described in any one embodiment may be applied to any other embodiment herein, and flowcharts or examples relating to one embodiment may be combined with any other embodiment in a suitable manner, done in different orders, or done in parallel. In addition, the systems and methods described herein may be performed in real time. It should also be noted, the systems and/or methods described above may be applied to, or used in accordance with, other systems and/or methods.

1-10. (canceled)

11. A method of manufacturing an extreme ultra-violet mask, the method comprising:
forming a reflective multilayer by alternately stacking two materials on a substrate;
inspecting the reflective multilayer by scanning the reflective multilayer with a laser beam;
forming an absorption layer on the reflective multilayer, wherein the absorption layer comprises a central transfer region and a non-transfer region; and
forming one or more holes in the absorption layer within the non-transfer region, wherein the one or more holes comprise a defect avoidance pattern exposing a beam calibration point of the reflective multilayer.

12. The method of claim 11, further comprising:
forming a capping layer on the reflective multilayer before scanning the reflective multilayer,
wherein the beam calibration point comprises a point at which a calibration laser beam is irradiated to the capping layer during the inspecting.

13. The method of claim 11, further comprising:
forming four defect avoidance patterns including the defect avoidance patterns, wherein the four defect avoidance patterns are symmetrical with respect to a center point of the substrate.

14. The method of claim 11, wherein an area of the defect avoidance pattern is equal to or greater than an area of the beam calibration point, and
the beam calibration point is located inside the defect avoidance pattern in a plan view.

15. The method of claim 11, wherein the defect avoidance pattern comprises a single hole or a plurality of micro-holes arranged in a 2D array.

16. The method of claim 11, wherein the defect avoidance pattern is not limited by resolution of an exposure process by extreme ultra-violet rays.

17. A method of manufacturing an extreme ultra-violet mask, the method comprising:
forming a reflective multilayer by alternately stacking two materials on a substrate;
inspecting the reflective multilayer by scanning the reflective multilayer with a laser beam;
forming an absorption layer on the reflective multilayer, wherein the absorption layer comprises a central transfer region and a non-transfer region; and
forming a plurality of process patterns in the non-transfer region,
wherein a first process pattern, which is one of the plurality of process patterns, exposes a beam calibration point of the reflective multilayer.

18. The method of claim 17, wherein a capping layer is formed on the reflective multilayer before scanning the reflective multilayer,
wherein the beam calibration point comprises a point at which a calibration laser beam is irradiated to the capping layer during the inspecting.

19. The method of claim 17, wherein the process patterns include an inspection pattern, an alignment pattern, a measurement pattern, a monitoring pattern, and an extreme ultra-violet scanning pattern.

20. The method of claim 17, wherein the first process pattern, comprising the beam calibration point, is formed on an upper surface of the reflective multilayer, wherein an area of the first process pattern is greater than or equal to an area of the beam calibration point.

21. A method of manufacturing an extreme ultra-violet mask, the method comprising:
forming a reflective multilayer by alternately stacking two materials on a substrate;
inspecting the reflective multilayer by scanning the reflective multilayer with a laser beam;
forming an absorption layer on the reflective multilayer, wherein the absorption layer comprises a central transfer region and a non-transfer region; and
forming an absorption pattern in the absorption layer,
wherein the inspecting includes:
performing beam calibration at a beam calibration point; and
performing scanning with a multi-laser beam,
wherein a blister defect is prevented based on beam calibration.

22. The method of claim 21, wherein, the beam calibration points do not overlap each other during the beam calibration.

23. The method of claim 21, wherein, the extreme ultra-violet mask is cooled during the beam calibration.

24. The method of claim 21, wherein, an anti-oxidant film is formed on a beam calibration point before or after the beam calibration.
